(19) United States
(12) Patent Application Publication
(10) Pub. No.: US 2026/0040518 A1
(43) Pub. Date: Feb. 5, 2026

(54) Static random access memory

(71) Applicant: UNITED MICROELECTRONICS CORP., Hsin-Chu City (TW)

(72) Inventors: Jun-Jie Wang, Changhua County (TW); Yu-Tse Kuo, Tainan City (TW); Tzu-Feng Chang, Tainan City (TW); Chun-Chieh Chang, Tainan City (TW)

(73) Assignee: UNITED MICROELECTRONICS CORP., Hsin-chu City. (TW)

(21) Appl. No.: 18/808,090

(22) Filed: Aug. 19, 2024

(30) Foreign Application Priority Data
Jul. 30, 2024 (TW) 113128202

(51) Int. Cl. H10B 10/00

(52) U.S. Cl. CPC H10B 10/12

(57) ABSTRACT

The invention provides a static random access memory, which comprises at least a first pull-up transistor (PU1), a first pull-down transistor (PD1), a second pull-up transistor (PU2), a second pull-down transistor (PD2), a first access transistor (PG1), a second access transistor (PG2), a first read port transistor (RPD) and a second read port transistor (RPD). The gate structures of the first pull-down transistor (PD1), the second pull-down transistor (PD2), the first access transistor (PG1) and the second access transistor (PG2) each include a P type work function metal layer, and an N type work function metal layer is located on the P type work function metal layer. The invention provides a static random access memory with low leakage current.

### BACKGROUND OF THE INVENTION

### 1. Field of the Invention

The invention relates to a static random access memory (SRAM), in particular to a structure of a static random access memory with low leakage current.

### 2. Description of the Prior Art

An embedded static random access memory (SRAM) comprises a logic circuit and a static random access memory connected to the logic circuit. SRAM is a kind of volatile memory cell, which means it preserves data only while power is continuously applied. SRAM is built of cross-coupled inverters that store data during the time that power remains applied, unlike dynamic random access memory (DRAM) that needs to be periodically refreshed. Because of its high access speed, SRAM is also used in computer systems as a cache memory.

### SUMMARY OF THE INVENTION

The invention provides a static random access memory, which at least comprises a substrate, wherein a plurality of fin structures are located on the substrate, and a plurality of gate structures are located on the substrate and span the plurality of fin structures, so as to form a plurality of transistors distributed on the substrate, wherein each transistor comprises a part of gate structures spanning a part of the fin structures, wherein a plurality of transistors comprise a first pull-up transistor (PU1), a first pull-down transistor (PD1), a second pull-up transistor (PU2) and a second pull-down transistor (PD2) to form a latch circuit, and a first access transistor (PG1) and a second access transistor (PG2) are connected to the latch circuit. And a first reading transistor (RPD) and a second reading transistor (RPG) which are connected in series with each other, wherein the gate structure of the first reading transistor (RPD) is connected with the gate structure of the first pull-down transistor (PD1), wherein the first pull-down transistor (PD1), the second pull-down transistor (PD2), the first access transistor (PG1) and the second access transistor (PG2) each comprise a gate structure, wherein the gate structures of the first pull-down transistor (PD1), the second pull-down transistor (PD2), the first access transistor (PG1) and the second access transistor (PG2) each include a P type work function metal layer, and an N type work function metal layer is located on the P type work function metal layer.

The invention also provides a static random access memory, which at least comprises a substrate, wherein a plurality of fin structures are located on the substrate, and a plurality of gate structures are located on the substrate and span the plurality of fin structures, so as to form a plurality of transistors distributed on the substrate, wherein each transistor comprises a part of gate structures spanning a part of the fin structures, wherein a plurality of transistors comprise a first pull-up transistor (PU1), a first pull-down transistor (PD1), a second pull-up transistor (PU2) and a second pull-down transistor (PD2) to form a latch circuit, and a first access transistor (PG1) and a second access transistor (PG2) are connected to the latch circuit. And a first reading transistor (RPD) and a second reading transistor (RPG) which are connected in series with each other, wherein the gate structure of the first reading transistor (RPD) is connected with the gate structure of the first pull-down transistor (PD1), wherein the first pull-down transistor (PD1), the second pull-down transistor (PD2), the first access transistor (PG1), the second access transistor (PG2), the first read transistor (RPD) and the second read transistor (RPG) each include a gate structure. The gate structures of the first pull-down transistor (PD1), the second pull-down transistor (PD2), the first access transistor (PG1), the second access transistor (PG2), the first reading transistor (RPD) and the second reading transistor (RPG) all contain a P type work function metal layer, and an N type work function metal layer is located on the P type work function metal layer.

The applicant found that there is still room for improvement in the leakage current of static random access memory, in which the leakage current of static random access memory is related to the Vt (threshold voltage) of each transistor, and the higher the Vt of each transistor, the lower the leakage current. In various embodiments of the present invention, by adding a P type work function metal layer to each transistor, the threshold voltage of each transistor is increased, thereby achieving the function of reducing the leakage current. Compared with only using ion doping to improve the threshold voltage of the transistor, the invention has a more significant effect of improving the threshold voltage.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

In order to make the following easier to understand, readers can refer to the drawings and their detailed descriptions at the same time when reading the present invention. Through the specific embodiments in the present specification and referring to the corresponding drawings, the specific embodiments of the present invention will be explained in detail, and the working principle of the specific embodiments of the present invention will be expounded. In addition, for the sake of clarity, the features in the drawings may not be drawn to the actual scale, so the dimensions of some features in some drawings may be deliberately enlarged or reduced.

FIG. 1 is a circuit diagram of a group of SRAM memory cells in a SRAM according to a first embodiment of the present invention.

FIG. 2 is a layout diagram of the SRAM of the present invention.

FIG. 3 is a schematic cross-sectional view of the gates of a pull-up transistor, a pull-down transistor/or a access transistor and a read transistor according to the first embodiment of the present invention.

FIG. 4 is a schematic cross-sectional view of the gates of a pull-up transistor, a pull-down transistor/or a access transistor and a read transistor according to a second embodiment of the present invention.

FIG. 5 is a schematic cross-sectional view of the gates of a pull-up transistor, a pull-down transistor/or a access transistor and a read transistor according to a third embodiment of the present invention.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

Although the present invention uses the terms first, second, third, etc. to describe elements, components, regions, layers, and/or sections, it should be understood that such elements, components, regions, layers, and/or sections should not be limited by such terms. These terms are only used to distinguish one element, component, region, layer and/or block from another element, component, region, layer and/or block. They do not imply or represent any previous ordinal number of the element, nor do they represent the arrangement order of one element and another element, or the order of manufacturing methods. Therefore, the first element, component, region, layer or block discussed below can also be referred to as the second element, component, region, layer or block without departing from the specific embodiments of the present invention.

The term “about” or “substantially” mentioned in the present invention usually means within 20% of a given value or range, such as within 10%, or within 5%, or within 3%, or within 2%, or within 1%, or within 0.5%. It should be noted that the quantity provided in the specification is approximate, that is, the meaning of “about” or “substantially” can still be implied without specifying “about” or “substantially”.

The terms “coupling” and “electrical connection” mentioned in the present invention include any direct and indirect means of electrical connection. For example, if the first component is described as being coupled to the second component, it means that the first component can be directly electrically connected to the second component, or indirectly electrically connected to the second component through other devices or connecting means.

Although the invention of the present invention is described below by specific embodiments, the inventive principles of the present invention can also be applied to other embodiments. In addition, in order not to obscure the spirit of the present invention, specific details are omitted, and the omitted details are within the knowledge of those with ordinary knowledge in the technical field.

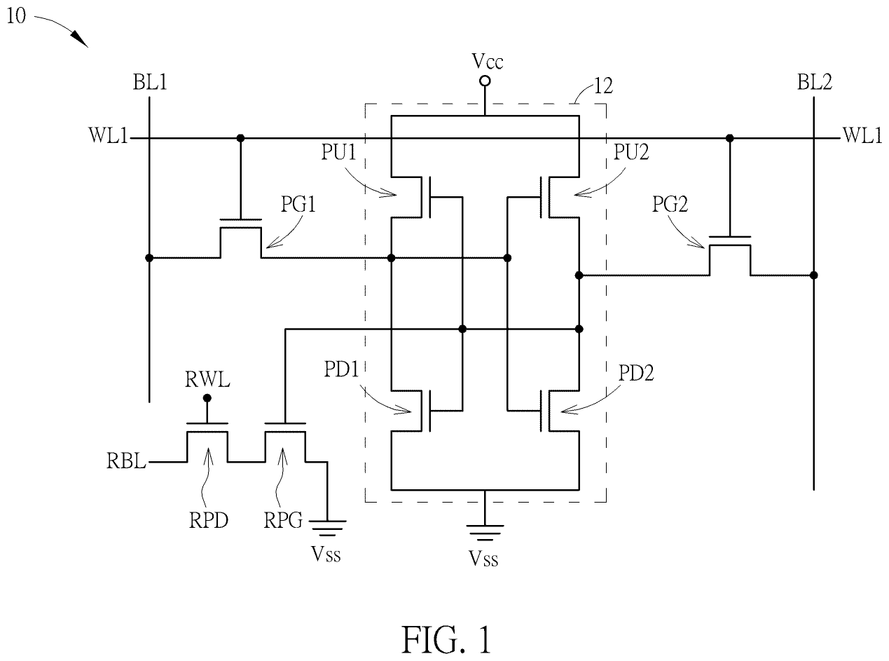

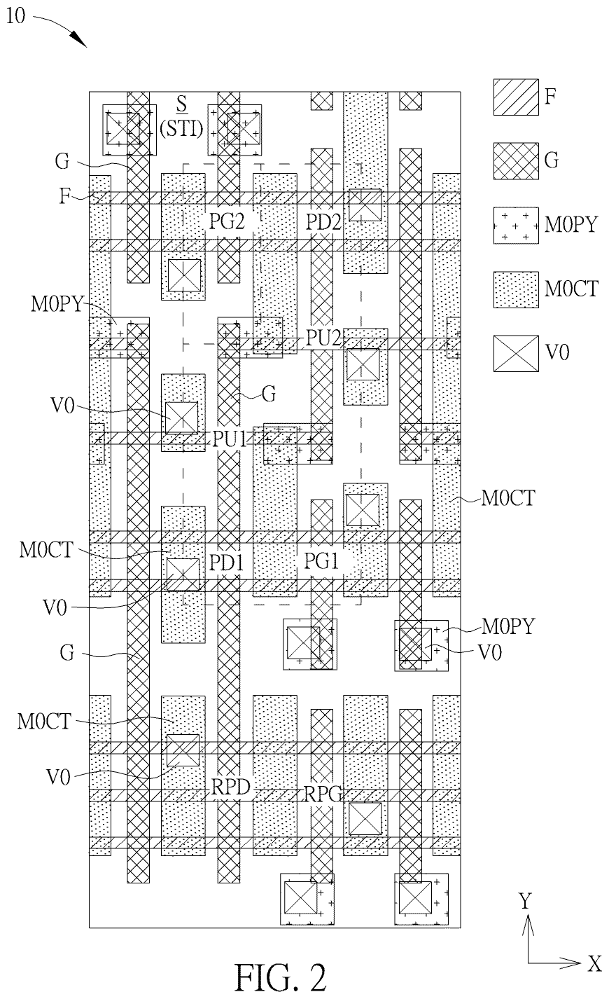

Please refer to FIG. 1 and FIG. 2. FIG. 1 is a circuit diagram of a group of SRAM memory cells in a SRAM according to a first embodiment of the present invention. FIG. 2 is a layout diagram of a static random access memory of the present invention.

In this embodiment, it includes at least one 8-transistor register file SRAM (8TRF-SRAM) memory cell 10. The 8TRF-SRAM memory cell 10 is preferably composed of a first Pull-Up transistor PU1, a second pull-up transistor PU2, a first pull-down transistor PD1, a second pull-down transistor PD2, a first access transistor PG1, a second access transistor PG2, a first reading transistor RPD and a second reading transistor RPG, wherein the first reading transistor RPD and the second reading transistor RPG are connected in series. The first pull-up transistor PU1 and the second pull-up transistor PU2, the first pull-down transistor PD1 and the second pull-down transistor PD2 form a latch circuit 12, so that data can be latched at a storage node. In addition, in this embodiment, a source region of each of the first pull-up transistor PU1 and the second pull-up transistor PU2 is electrically connected to a voltage source Vcc, and a drain region of each of the first pull-down transistor PD1 and the second pull-down transistor PD2 is electrically connected to a voltage source Vss.

As for the gates of the first access transistor PG1 and the second access transistor PG2, they are coupled to the word line WL1, while the source of the first access transistor PG1 and the second access transistor PG2 are respectively coupled to the corresponding first bit line BL1 and second bit line BL2. In addition, the gate of the first reading transistor RPD is connected to a reading word line RWL, the source of the first reading transistor RPD is connected to a reading bit line RBL, the gate of the reading transistor RPD is connected to the latch circuit 12, and the drain of the reading transistor RPD is connected to the voltage source Vss.

FIG. 2 is a layout diagram of a static random access memory of the present invention. In this embodiment, as shown in FIG. 2, the 8TRF-SRAM memory cell 10 is disposed on a substrate S, such as a silicon substrate or a silicon-on-insulator (SOI) substrate. The substrate S can be a planar structure or provided with a plurality of fin structures F, and a plurality of gate structures G are located on the substrate S. In other embodiments of the present invention, it can also be applied to planar SRAM, which means that it is not necessary to form fin structures on the substrate, but to form doped regions in the substrate, which is also within the scope of the present invention.

In addition, the layout of FIG. 2 also includes a plurality of metal layers, in which the metal layers partially connecting the gates of transistors are defined as M0PY, and the metal layers connecting the source/drain of transistors is defined as M0CT. In FIG. 2, the metal layers M0PY and the metal layers M0CT are respectively represented by different patterns. In fact, the difference between the metal layer M0PY and the metal layer M0CT lies in the different connected elements. However, both of them actually belong to the metal layers and can contain the same material, but they are not limited to this. FIG. 2 also includes a plurality of contact plugs (via) V0, wherein the contact plugs V0 are used to connect the metal layers M0PY and M0CT to other conductive layers (such as M1, V1, M2, etc., which are common in the semiconductor manufacturing process).

In the layout pattern of the present invention, a three-dimensional SRAM is taken as an example (that is, fin structures F are formed to replace planar doped regions). As shown in FIG. 2, the substrate S is covered with an insulating layer, such as a shallow trench isolation structure (STI), except for the fin structure F, the gate structure G, the connecting structure M0PY, the connecting structure M0CT and the position of the contact V0, so as to isolate electronic components (such as transistors) from short circuit. In addition, each gate structure G straddles a part of the fin structure F to form transistors (for example, the first pull-up transistor PU1, the second pull-up transistor PU2, the first pull-down transistor PD1, the second pull-down transistor PD2, the first access transistor PG1, the second access transistor PG2, the first read transistor RPD and a second read transistor RPG). For the sake of clarity, the positions of the above-mentioned transistors are directly marked on the second figure, especially at the intersection of the gate structure G and the fin structure F.

In the first embodiment, the first pull-up transistor PU1, the second pull-up transistor PU2, the first pull-down transistor PD1, the second pull-down transistor PD2, the first access transistor PG1, the second access transistor PG2, the first read transistor RPD and the second read transistor RPG each include a gate structure G, the first pull-up transistor PU1 and the second pull-up transistor PU2 are composed of P type metal oxide semiconductor transistors (PMOS), while the first pull-down transistor PD1, the second pull-down transistor PD2, the first access transistor PG1, the second access transistor PG2, the first read transistor RPD and the second read transistor RPG are composed of N type metal oxide semiconductor (NMOS). Therefore, from the sectional view, the stacked material layers of each gate structure are different, and the obvious difference is that PMOS transistors usually have an extra P type work function metal layer in the stacked material layer of the gate compared with NMOS transistors.

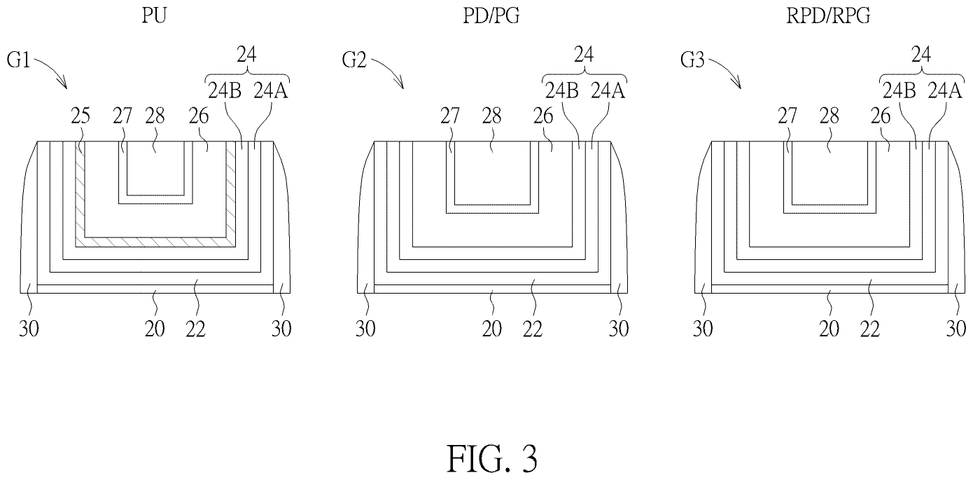

In more detail, please refer to FIG. 3, which shows the schematic cross-sectional structure of the gates of a pull-up transistor, a pull-down transistor/or a access transistor and a read transistor according to the first embodiment of the present invention. In FIG. 3, “PU” represents a pull-up transistor, including the first pull-up transistor PU1 and/or the second pull-up transistor PU2, and in FIG. 3, a gate structure G1 represents the gate structure of the above transistors; “PD” stands for pull-down transistor, including the first pull-down transistor PD1 and/or the second pull-down transistor PD2, while “PG” stands for access transistor, including the first access transistor PG1 and the second access transistor PG2. In FIG. 3, the gate structures of the above transistors (the first pull-down transistor PD1, the second pull-down transistor PD2, the first access transistor PG1 and the second access transistor PG2) are represented by gate structures G2. “RPD/RPG” represents the first reading transistor RPD and the second reading transistor RPG, and the gate structure of the above transistors is represented by the gate structure G3 in FIG. 3. For simplicity, some components such as substrate, dielectric layer, shallow trench isolation, source/drain regions are not shown, but those skilled in the art should know that these components exist in the semiconductor structure of the present invention.

As shown in FIG. 3, the gate structure G1, the gate structure G2 and the gate structure G3 each include a gate dielectric layer 20, a high dielectric constant (high-k) layer 22, a bottom barrier layer 24, an N type work function metal layer 26, a diffusion barrier layer 27 and an electrode layer 28 stacked from bottom to top, wherein if a gate groove (not shown) is formed in the dielectric layer first, and then the above-mentioned material layers are sequentially formed in the gate groove, then the cross section of each material layer presents a “U” shape. On the other hands, if the above material layers are stacked on a plane, the cross section shows a “-” shape. Next, spacers 30 are included on both sides of the stacked structure.

In this embodiment, the material of the gate dielectric layer 20 is silicon oxide, for example. The high dielectric constant layer 22 can be selected from a dielectric material with a dielectric constant (k value) larger than 4 such as metallic oxide, such as hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta2O₉, SBT), lead zirconate titanate (PbZrxTi₁-xO₃, PZT), barium strontium titanate (BaxSr₁-xTiO₃, BST) or a combination thereof. The bottom barrier layer 24 may include a lower titanium nitride (TiN) layer 24A and an upper tantalum nitride (TaN) layer 24B, wherein the thickness of the titanium nitride (TiN) layer 24A is about 10-20 angstroms, and the thickness of the tantalum nitride (TaN) layer 24B is about 10-20 angstroms. The material of the N type work function metal layer 26 is, for example, titanium aluminide (TiAl), and the thickness of the N type work function metal layer 26 is about 20-60 angstroms. The diffusion barrier layer 27 is made of titanium nitride, for example, and has a thickness of about 10 angstroms. The material of the electrode layer 28 is, for example, tungsten (W) or aluminum (Al). The material of the spacer 30 is, for example, silicon oxide, silicon nitride, silicon oxynitride, etc., but the materials of the above-mentioned material layers are only some examples of the present invention, and the present invention is not limited to this.

Notably, in addition to the above-mentioned gate dielectric layer 20, high dielectric constant layer 22, bottom barrier layer 24, N type work function metal layer 26 and top electrode layer 28, the gate structure G1 (corresponding to the first pull-up transistor PU1 and/or the second pull-up transistor PU2) further includes a P type work function metal layer 25 located between the bottom barrier layer 24 and the N type work function metal layer 26. That is to say, from a cross-sectional view, the tantalum nitride (TaN) layer 24B of the bottom barrier layer 24 in the gate structure G1 directly contacts the P type work function metal layer 25, and the N type work function metal layer 26 also directly contacts the P type work function metal layer 25. In this embodiment, the material of the P type work function metal layer 25 is, for example, titanium nitride (TiN), and the thickness is about 8-16 angstroms, but the present invention is not limited to this.

In contrast, the gate structure G2 (corresponding to the first pull-down transistor PD1, the second pull-down transistor PD2, the first access transistor PG1 and the second access transistor PG2) and the gate structure G3 (corresponding to the first read transistor RPD and the second read transistor RPG) in this embodiment do not include the P type work function metal layer 25. That is, the tantalum nitride (TaN) layer 24B of the bottom barrier layer 24 in the gate structure G2 and the gate structure G3 directly contacts the N type work function metal layer 26.

The applicant found that in the first embodiment, there is still room for improvement in the leakage current of the 8TRF-SRAM memory cell 10. More specifically, the leakage current of the 8TRF-SRAM memory cell 10 is related to the Vt (threshold voltage) of each transistor, and the higher the Vt of the transistor, the lower the leakage current. The Vt of transistors can be improved by doping ions, but the range of adjusting the Vt of transistors by doping ions is limited. Therefore, in other embodiments of the present invention, the applicant proposes a method of adding a work function metal layer to improve the threshold voltage of each transistor, thereby achieving the function of reducing leakage current. See the following paragraphs for details.

In the following, different embodiments of the SRAM of the present invention will be described, and in order to simplify the description, the following description will mainly focus on the differences of each embodiment, without repeating the similarities. In addition, the same elements in various embodiments of the present invention are labeled with the same reference numerals, so as to facilitate the comparison among various embodiments.

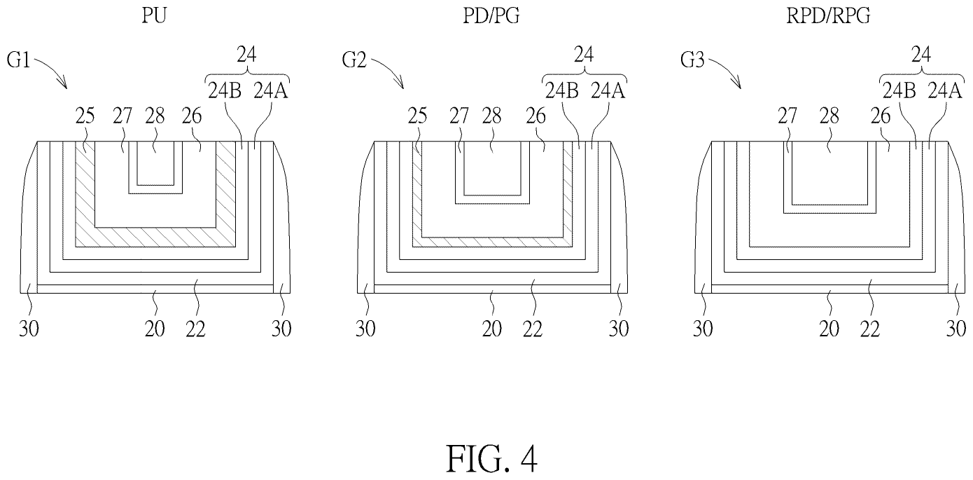

FIG. 4 is a schematic cross-sectional view of the gates of a pull-up transistor, a pull-down transistor/or a access transistor and a read transistor according to a second embodiment of the present invention. As shown in FIG. 4, this embodiment also proposes an 8TRF-SRAM memory cell, and its circuit diagram and layout pattern are the same as those of the first embodiment, so it can be shown with reference to FIG. 1 and FIG. 2, and will not be repeated here.

This embodiment is different from the above-mentioned first embodiment in that the gate structure G1 (corresponding to the first pull-up transistor PU1 and/or the second pull-up transistor PU2) includes the P type work function metal layer 25, and the gate structure G2 (corresponding to the first pull-down transistor PD1, the second pull-down transistor PD2, the first access transistor PG1 and the second access transistor PG2) also includes the P type work function metal layer 25, while the gate structure G3 (corresponding to the first pull-down transistor PD1 and the second access transistor PG2) do not include the P type work function metal layer 25. In addition, the thickness of the P type work function metal layer 25 in the gate structure G1 is about 16-32 angstroms, while the thickness of the P type work function metal layer 25 in the gate structure G2 is about 8-16 angstroms, that is, the thickness of the P type work function metal layer 25 in the gate structure G1 is greater than the thickness of the P type work function metal layer 25 in the gate structure G2.

In this embodiment, besides the gate structure G1, the P type work function metal layer 25 is also added to the gate structure G2, so the threshold voltages of the first pull-down transistor PD1, the second pull-down transistor PD2, the first access transistor PG1 and the second access transistor PG2 can be increased by adding the P type work function metal layer 25, thereby reducing the leakage current of the whole SRAM and improving the quality of the device.

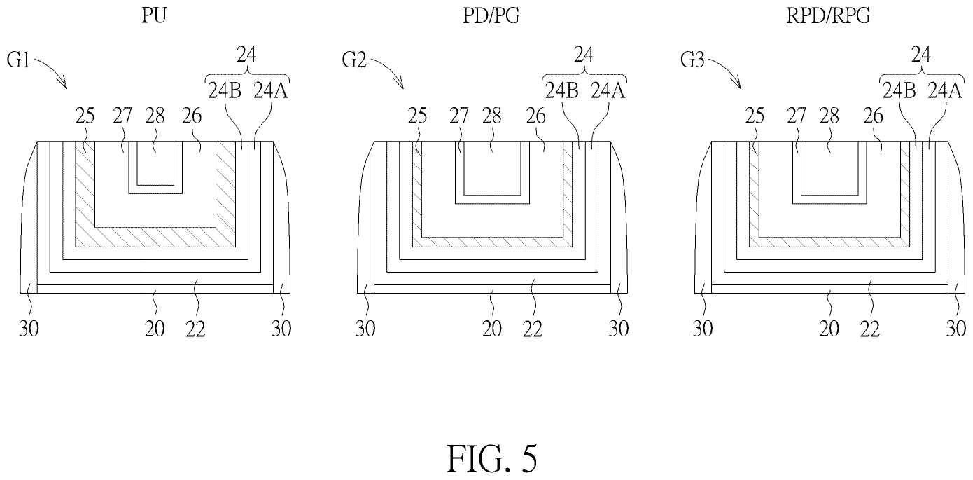

In addition, in the second embodiment, only the gate structure G1 and the gate structure G2 contain the P type work function metal layer 25, while the gate structure G3 does not contain the P type work function metal layer 25. However, in the third embodiment of the present invention, the gate structure G1, the gate structure G2 and the gate structure G3 may all include the P type work function metal layer 25. Please refer to FIG. 5, which shows a schematic cross-sectional structure of the gates of a pull-up transistor, a pull-down transistor/or a access transistor and a read transistor according to a third embodiment of the present invention. As shown in FIG. 5, this embodiment also proposes an 8TRF-SRAM memory cell, the circuit diagram and layout pattern of which are the same as those of the first embodiment, so you can refer to FIG. 1 and FIG. 2, and will not repeat them here.

This embodiment is different from the above-mentioned first embodiment in that except that the gate structure G1 (corresponding to the first pull-up transistor PU1 and/or the second pull-up transistor PU2) includes the P type work function metal layer 25, the gate structure G2 (corresponding to the first pull-down transistor PD1, the second pull-down transistor PD2, the first access transistor PG1 and the second access transistor PG2) and the gate structure G3 (corresponding to the first read transistor RPD and the second read transistor RPG) also contain a p-type work function metal layer 25 respectively. In addition, the thickness of the P type work function metal layer 25 in the gate structure G1 is about 16-32 angstroms, while the thickness of the P type work function metal layer 25 in the gate structure G2 and the gate structure G3 is about 8-16 angstroms, that is, the thickness of the P type work function metal layer 25 in the gate structure G1 is greater than that in the gate structures G2 or G3. The thickness of the P type work function metal layer 25 of the gate structure G2 is preferably equal to the thickness of the P type work function metal layer 25 of the gate structure G3.

In order to form the P type work function metal layer 25 with different thicknesses, in the actual process, the P type work function metal layer 25 can be formed in each gate groove, then the grooves of the gate structure G2 and the gate structure G3 are covered, and the P type work function metal layer 25 (for example, TiN) with the same material is formed again in the groove of the gate structure G1, and then the material layers such as the N type work function metal layer 26 can be continuously formed. The details of other processes are known in the art, so they are not detailed here.

In this embodiment, the P type work function metal layer 25 is added to all transistors, so compared with the first embodiment, the threshold voltage of each transistor can be effectively increased, and the leakage current of the SRAM can be further reduced. According to the applicant's experimental observation, compared with the first embodiment, the leakage current of the static random access memory in the off state is reduced by about 80%, so the effects of reducing the leakage current and improving the device quality can be achieved.

According to the above description and drawings, the present invention provides a static random access memory (refer to the embodiment of FIG. 4), which at least includes a substrate S, a plurality of fin structures F located on the substrate S, and a plurality of gate structures G located on the substrate S and spanning the fin structures F to form a plurality of transistors distributed on the substrate, wherein each transistor includes a part of the gate structure G spanning the part of the fin structures F, wherein a plurality of transistors comprise a first pull-up transistor (PU1), a first pull-down transistor (PD1), a second pull-up transistor (PU2) and a second pull-down transistor (PD2) to form a latch circuit, and a first access transistor (PG1) and a second access transistor (PG2) are connected to the latch circuit. And a first reading transistor (RPD) and a second reading transistor (RPG) which are connected in series with each other, wherein the gate structure of the first reading transistor (RPD) is connected with the gate structure of the first pull-down transistor (PD1), wherein the first pull-down transistor (PD1), the second pull-down transistor (PD2), the first access transistor (PG1) and the second access transistor (PG2) each include a gate structure (such as the gate structure G2 in FIG. 4), in which the gate structures G2 of the first pull-down transistor (PD1), the second pull-down transistor (PD2), the first access transistor (PG1) and the second access transistor (PG2) each include a P type work function metal layer 25, and an N type work function metal layer 26 is located on the P type work function metal layer 25.

In some embodiments of the present invention, in the gate structure G2 of the first pull-down transistor (PD1), the second pull-down transistor (PD2), the first access transistor (PG1) and the second access transistor (PG2), the material of the P type work function metal layer 25 comprises titanium nitride, and the material of the N type work function metal layer 26 comprises titanium aluminide.

In some embodiments of the present invention, the P type work function metal layer 25 directly contacts the N type work function metal layer 26.

In some embodiments of the present invention, the gate structures G2 respectively included in the first pull-down transistor (PD1), the second pull-down transistor (PD2), the first access transistor (PG1) and the second access transistor (PG2) further include a bottom barrier layer 24 below the P type work function metal layer 25, a diffusion barrier layer 27 above the N type work function metal layer 26, and an electrode layer 28 above the diffusion barrier layer 27.

In some embodiments of the present invention, the bottom barrier layer 24 comprises a stacked structure of a titanium nitride layer 24A and a tantalum nitride layer 24B, the tantalum nitride layer 24B is located above the titanium nitride layer 24A, and the tantalum nitride layer 24B directly contacts the P type work function metal layer 25.

In some embodiments of the present invention, in which the diffusion barrier layer 27 comprises titanium nitride, the diffusion barrier layer 27 directly contacts the N type work function metal layer 26.

In some embodiments of the present invention, the material of the electrode layer 28 comprises tungsten or aluminum.

In some embodiments of the present invention, the first reading transistor (RPD) and the second reading transistor (RPG) each include a gate structure G3, and the gate structures G3 of the first reading transistor (RPD) and the second reading transistor (RPG) each include an N type work function metal layer 26, and a bottom barrier layer 24 is located below the N type work function metal layer 26.

In some embodiments of the present invention, in the respective gate structures G3 of the first reading transistor (RPD) and the second reading transistor (RPG), the bottom barrier layer 24 comprises a stacked structure of a titanium nitride layer 24A and a tantalum nitride layer 24B, the tantalum nitride layer 24B is located above the titanium nitride layer 24A, and the tantalum nitride layer 24B directly contacts the N type work function metal layer 26 (as shown in FIG. 4, In the gate structure G3 does not include the P type work function metal layer 25, so the N type work function metal layer 26 directly contacts the tantalum nitride layer 24B).

In some embodiments of the present invention, the first pull-up transistor (PU1) and the second pull-up transistor (PU2) each include a gate structure G1, and the gate structures G1 of the first pull-up transistor (PU1) and the second pull-up transistor (PU2) each include an N type work function metal layer 26 and a P type work function metal layer 25.

In some embodiments of the present invention, a thickness of the P type work function metal layer 25 in the gate structure G1 of the first pull-up transistor (PU1) is greater than a thickness of the P type work function metal layer 25 in the gate structure G2 of the first pull-down transistor (PD1).

The present invention also provides a static random access memory (refer to the embodiment in FIG. 5), which at least includes a substrate S, a plurality of fin structures F located on the substrate S, and a plurality of gate structures G located on the substrate S and spanning the plurality of fin structures F to form a plurality of transistors distributed on the substrate, wherein each transistor includes a part of the gate structure G spanning the part of the fin structures F, wherein a plurality of transistors comprise a first pull-up transistor (PU1), a first pull-down transistor (PD1), a second pull-up transistor (PU2) and a second pull-down transistor (PD2) to form a latch circuit, and a first access transistor (PG1) and a second access transistor (PG2) are connected to the latch circuit. And a first reading transistor (RPD) and a second reading transistor (RPG) which are connected in series with each other, wherein the gate structure of the first reading transistor (RPD) is connected with the gate structure of the first pull-down transistor (PD1), wherein the first pull-down transistor (PD1), the second pull-down transistor (PD2), the first access transistor (PG1), the second access transistor (PG2), the first read transistor (RPD) and the second read transistor (RPG) each include a gate structure (i.e., the gate structure G2 and the gate structure G3 in FIG. 5). The gate structures G2 and G3 of the first pull-down transistor (PD1), the second pull-down transistor (PD2), the first access transistor (PG1), the second access transistor (PG2), the first read transistor (RPD) and the second read transistor (RPG) all contain a P type work function metal layer 25, and an N type work function metal layer 26 is located on the P type work function metal layer 25.

In some embodiments of the present invention, in the gate structures G2 and G3 of the first pull-down transistor (PD1), the second pull-down transistor (PD2), the first access transistor (PG1), the second access transistor (PG2), the first read transistor (RPD) and the second read transistor (RPG), the material of P type work function metal layer 25 contains titanium nitride, and the material of N type work function metal layer 26 contains titanium aluminide.

In some embodiments of the present invention, the P type work function metal layer 25 directly contacts the N type work function metal layer 26.

In some embodiments of the present invention, the gate structures G2 and G3 of the first pull-down transistor (PD1), the second pull-down transistor (PD2), the first access transistor (PG1), the second access transistor (PG2), the first read transistor (RPD) and the second read transistor (RPG) respectively further include a bottom barrier layer 24 located below the P type work function metal layer 25.

In some embodiments of the present invention, the bottom barrier layer 24 comprises a stacked structure of a titanium nitride layer 24A and a tantalum nitride layer 24B, the tantalum nitride layer 24B is located above the titanium nitride layer 24A, and the tantalum nitride layer 24B directly contacts the P type work function metal layer 25.

In some embodiments of the present invention, in which the diffusion barrier layer 27 comprises titanium nitride, the diffusion barrier layer 27 directly contacts the N type work function metal layer 26.

In some embodiments of the present invention, the material of the electrode layer 28 comprises tungsten or aluminum.

In some embodiments of the present invention, the first pull-up transistor (PU1) and the second pull-up transistor (PU2) each include a gate structure G1, and the gate structures G1 of the first pull-up transistor (PU1) and the second pull-up transistor (PU2) each include an N type work function metal layer 26 and a P type work function metal layer 25.

In some embodiments of the present invention, the thickness of the P type work function metal layer 25 in the gate structure G1 of the first pull-up transistor (PU1) is greater than that of the P type work function metal layer 25 in the gate structure G3 of the first read-out transistor (RPD), wherein the thickness of the P type work function metal layer 25 in the gate structure G3 of the first read-out transistor (RPD) is equal to that of the gate structure G2 of the first pull-down transistor (PD1).

The applicant found that there is still room for improvement in the leakage current of static random access memory, in which the leakage current of static random access memory is related to the Vt (threshold voltage) of each transistor, and the higher the Vt of each transistor, the lower the leakage current. In various embodiments of the present invention, by adding a P type work function metal layer to each transistor, the threshold voltage of each transistor is increased, thereby achieving the function of reducing the leakage current. Compared with only using ion doping to improve the threshold voltage of the transistor, the invention has a more significant effect of improving the threshold voltage.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A static random access memory (SRAM), at least comprising:
a substrate;
a plurality of fin structures located on the substrate;
a plurality of gate structures located on the substrate and span the plurality of fin structures to form a plurality of transistors distributed on the substrate, wherein each transistor comprises a part of the gate structure spanning a part of the fin structure, and the plurality of transistors comprise:
a first pull-up transistor (PU1), a first pull-down transistor (PD1), a second pull-up transistor (PU2) and a second pull-down transistor (PD2) together form a latch circuit;
a first access transistor (PG1) and a second access transistor (PG2) connected to the latch circuit; and
a first reading transistor (RPD) and a second reading transistor (RPG) connected in series, wherein the gate structure of the first reading transistor (RPD) is connected to the gate structure of the first pull-down transistor (PD1);
wherein the first pull-down transistor (PD1), the second pull-down transistor (PD2), the first access transistor (PG1) and the second access transistor (PG2) each comprise a gate structure, wherein the gate structures of the first pull-down transistor (PD1), the second pull-down transistor (PD2), the first access transistor (PG1) and the second access transistor (PG2) each include a P type work function metal layer, and an N type work function metal layer is located on the P type work function metal layer.

2. The SRAM according to claim 1, wherein in the gate structures of the first pull-down transistor (PD1), the second pull-down transistor (PD2), the first access transistor (PG1) and the second access transistor (PG2), the material of the P type work function metal layer comprises titanium nitride, and the material of the N type work function metal layer comprises titanium aluminide.

3. The SRAM according to claim 2, wherein the P type work function metal layer directly contacts the N type work function metal layer.

4. The SRAM according to claim 1, wherein the gate structures of the first pull-down transistor (PD1), the second pull-down transistor (PD2), the first access transistor (PG1) and the second access transistor (PG2) respectively further comprise a bottom barrier layer under the P type work function metal layer, a diffusion barrier layer disposed on the N type work function metal layer, and an electrode layer disposed on the diffusion barrier layer.

5. The SRAM according to claim 4, wherein the bottom barrier layer comprises a stacked structure of a titanium nitride layer and a tantalum nitride layer, the tantalum nitride layer is located above the titanium nitride layer, and the tantalum nitride layer directly contacts the P type work function metal layer.

6. The SRAM according to claim 4, wherein the diffusion barrier layer comprises titanium nitride, and the diffusion barrier layer directly contacts the N type work function metal layer.

7. The SRAM according to claim 4, wherein the material of the electrode layer comprises tungsten or aluminum.

8. The SRAM according to claim 1, wherein the first reading transistor (RPD) and the second reading transistor (RPG) each comprise a gate structure, and the gate structures of the first reading transistor (RPD) and the second reading transistor (RPG) each comprise an N type work function metal layer, and a bottom barrier layer is located below the N type work function metal layer.

9. The SRAM according to claim 8, wherein in the gate structures of the first reading transistor (RPD) and in the gate of the second reading transistor (RPG), the bottom barrier layer comprises a stacked structure of a titanium nitride layer and a tantalum nitride layer, the tantalum nitride layer is located above the titanium nitride layer, and the tantalum nitride layer directly contacts the N type work function metal layer.

10. The SRAM according to claim 1, wherein the first pull-up transistor (PU1) and the second pull-up transistor (PU2) each comprise a gate structure, and the gate structures of the first pull-up transistor (PU1) and the second pull-up transistor (PU2) each comprise an N type work function metal layer and a P type work function metal layer.

11. The SRAM according to claim 10, wherein a thickness of the P type work function metal layer in the gate structure of the first pull-up transistor (PU1) is greater than a thickness of the P type work function metal layer in the gate structure of the first pull-down transistor (PD1).

12. A static random access memory, comprising at least:
a substrate;
a plurality of fin structures located on the substrate;
a plurality of gate structures located on the substrate and span the plurality of fin structures to form a plurality of transistors distributed on the substrate, wherein each transistor comprises a part of the gate structure spanning a part of the fin structure, and the plurality of transistors comprise:
a first pull-up transistor (PU1), a first pull-down transistor (PD1), a second pull-up transistor (PU2) and a second pull-down transistor (PD2) together form a latch circuit;
a first access transistor (PG1) and a second access transistor (PG2) connected to the latch circuit; and
a first reading transistor (RPD) and a second reading transistor (RPG) connected in series, wherein the gate structure of the first reading transistor (RPD) is connected to the gate structure of the first pull-down transistor (PD1);
wherein the first pull-down transistor (PD1), the second pull-down transistor (PD2), the first access transistor (PG1), the second access transistor (PG2), the first read transistor (RPD) and the second read transistor (RPG) each comprise a gate structure, wherein the gate structures of the first pull-down transistor (PD1), the second pull-down transistor (PD2), the first access transistor (PG1), the second access transistor (PG2), the first read transistor (RPD) and the second read transistor (RPG) all contain a P type work function metal layer, and an N type work function metal layer is located on the P type work function metal layer.

13. The SRAM according to claim 12, wherein in the gate structures of the first pull-down transistor (PD1), the second pull-down transistor (PD2), the first access transistor (PG1), the second access transistor (PG2), the first read transistor (RPD) and the second read transistor (RPG), the material of the P type work function metal layer contains titanium nitride, and the material of the N type work function metal layer contains titanium aluminide.

14. The SRAM according to claim 13, wherein the P type work function metal layer directly contacts the N type work function metal layer.

15. The SRAM according to claim 12, wherein the gate structures of the first pull-down transistor (PD1), the second pull-down transistor (PD2), the first access transistor (PG1), the second access transistor (PG2), the first read transistor (RPD) and the second read transistor (RPG) further comprise a bottom barrier layer disposed below the P type work function metal layer, a diffusion barrier layer disposed on the N type work function metal layer, and an electrode layer disposed on the diffusion barrier layer.

16. The SRAM according to claim 15, wherein the bottom barrier layer comprises a stacked structure of a titanium nitride layer and a tantalum nitride layer, the tantalum nitride layer is located above the titanium nitride layer, and the tantalum nitride layer directly contacts the P type work function metal layer.

17. The SRAM according to claim 15, wherein the diffusion barrier layer comprises titanium nitride, and the diffusion barrier layer directly contacts the N type work function metal layer.

18. The SRAM according to claim 15, wherein the material of the electrode layer comprises tungsten or aluminum.

19. The SRAM according to claim 12, wherein the first pull-up transistor (PU1) and the second pull-up transistor (PU2) each comprise a gate structure, and the gate structures of the first pull-up transistor (PU1) and the second pull-up transistor (PU2) each comprise an N type work function metal layer and a P type work function metal layer.

20. The SRAM according to claim 19, wherein a thickness of the P type work function metal layer in the gate structure of the first pull-up transistor (PU1) is greater than a thickness of the P type work function metal layer in the gate structure of the first read transistor (RPD), wherein the thickness of the P type work function metal layer in the gate structure of the first read transistor (RPD) is equal to a thickness of the P type work function metal layer in the gate structure of the first pull-down transistor (PD1).
